(19) United States
(12) Patent Application Publication
(10) Pub. No.: US 2025/0364308 A1
(43) Pub. Date: Nov. 27, 2025

(54) NON-DEFORMING KINEMATIC COUPLING

(71) Applicant: Applied Materials Israel Ltd., Rehovot (IL)

(72) Inventors: David AMARILIO, Rehovot (IL); Dima APTER, Rehovot (IL); Mariano ABRAMSON, Rehovot (IL)

(21) Appl. No.: 19/219,963

(22) Filed: May 27, 2025

(30) Foreign Application Priority Data
May 27, 2024 (IL) 313148

(51) Int. Cl. H01L 21/687; H01F 7/02; H01L 21/68

(52) U.S. Cl. CPC H01L 21/68785; H01F 7/0252; H01L 21/68

(57) ABSTRACT

A kinematic coupling for providing a preloading force without inducing deformation of the members being coupled, including a first member of a kinematic coupling, a second member of the kinematic coupling, and an attractive force component attached to at least one of the members of the kinematic coupling to attract the other member, wherein the attractive force component is located at a location coaxial with an axis of the kinematic coupling, thereby providing an attraction force between the first member and the second member directed along the axis of the kinematic coupling. Related apparatus and methods are also described.

### RELATED APPLICATIONS

This application claims the benefit of priority from Israeli Application No. 313148, filed May 27, 2024, which is incorporated herein by reference.

### TECHNOLOGICAL FIELD

The present disclosure, in some embodiments thereof, relates to a kinematic coupling and, more particularly, but not exclusively, to devices and methods for kinematic coupling which can increase coupling force without inducing deformation in the members being coupled.

### BACKGROUND

A kinematic coupling is a separable joint between two members of a mechanical system. It locates and connects the two separate members together. Such a joint may include electrical and or optical interfaces.

U.S. Pat. No. 5,711,647 to Slocum describes a system for achieving a high degree of location and orientation accuracy and repeatability of a part, such as a semiconductor wafer, for storage of the part in a cassette or placement on a process tool while being able to grasp the part, while maintaining maximally repeatable location, orientation, and cleanliness, while moving it from one tool to another, such as a process tool to a cassette. This is accomplished by providing in one case a pattern of six grooves on the circumference of a part, typically spaced 60 angular degrees apart, and a pattern of three curved contact surfaces on a gripper plate and three curved contact surfaces on a tool plate, where the plates nest such that the three curved surfaces on the gripper plate would make contact with the sides of three of the grooves in the part, and when the gripper plate that is holding the part lowers the part onto the tool plate, the three curved surfaces on the tool plate would make contact with the sides of three of the other grooves in the part as the part is unloaded from the gripper plate and comes to rest on the tool plate. Thus at all times the part position is kinematically uniquely established and mathematically defined in space which provides a high degree of repeatability, and furthermore minimizes stresses placed on the part that would otherwise occur from the typical action of clamping-type gripping mechanisms. In the second case, where it is not feasible to put grooves in the parts, the same nesting plates would each have three sets of support units that each have orthogonal curved surfaces such that when a part rests on the support points, three of the support point curved surfaces support the weight of the part, and the other three orthogonal points restrain the lateral position, In either case, the plates can be stacked horizontally, or at an inclined angle.

U.S. Pat. No. 4,574,625 to Olasz et al. describes a surface finish, displacement and contour scanner is disclosed which effectively protects its stylus from damage even if the stylus meets an obstacle, such as a wall, a major ridge or a crack. The surface finish, displacement and contour scanner further includes a unique transducer designed to provide true displacement transducer operation with or without traverse, a magnetic attach-release mechanism disposed median between the stylus and a transducer, and a ball-and-notch seating structure formed about the point of flexing of the stylus support.

U.S. Pat. No. 5,678,944 to Slocum et al. describes a novel flexural mount kinematic coupling apparatus and technique in which a pair of surfaces is deterministically kinematically coupled with repeatable accuracy of positioning with respect to one another and an intermediate plane between, and with guided compliance provided by flexural, rolling or sliding bearing elements to permit translational clamping in a direction normal to the plane that brings the surfaces into contact without positional error motions between the surfaces.

### BRIEF DESCRIPTION OF THE DRAWING(S)

Some embodiments of the disclosure are herein described, by way of example only, with reference to the accompanying drawings. With specific reference now to the drawings in detail, it is stressed that the particulars shown are by way of example and for purposes of illustrative discussion of embodiments of the disclosure. In this regard, the description taken with the drawings makes apparent to those skilled in the art how embodiments of the disclosure may be practiced.

In the drawings:

FIG. 1A is a simplified line drawing of an isometric view of a kinematic coupling termed a Maxwell kinematic coupling according to prior art;

FIG. 1B is a simplified line drawing of an isometric view of a kinematic coupling termed a Kelvin kinematic coupling according to prior art;

FIGS. 2A and 2B are simplified line drawings of views of a Maxwell kinematic coupling when its members are coupled, according to prior art;

FIG. 3A is a simplified line drawing of a cross section of a Maxwell kinematic coupling showing forces acting upon a chuck;

FIG. 3B is a simplified line drawing of a cross section of a Maxwell kinematic coupling showing added force acting upon a chuck;

FIG. 4 is a simplified line drawing of a cross section of a Maxwell kinematic coupling showing added force acting upon a chuck, according to an example;

FIG. 5A is a simplified line drawing of a cross section of a Maxwell kinematic coupling showing an arrangement for adding preloading force for coupling the kinematic coupling according to an example;

FIG. 5B is a simplified line drawing of a cross section of a Maxwell kinematic coupling showing an arrangement for adding force for coupling the kinematic coupling according to an example; and

FIG. 6 is a simplified flow chart illustration of a method for increasing a coupling force between members of a kinematic coupling without inducing deformation of the members being coupled, according to an example.

### DETAILED DESCRIPTION OF EXAMPLES

The present disclosure, in some embodiments thereof, relates to a kinematic coupling and, more particularly, but not exclusively, to devices and methods for kinematic coupling which can increase coupling force without inducing deformation in the members being coupled.

### Overview

There are six degrees of natural or rigid body freedom, i.e. potential movements in a mechanical system. Kinematic couplings are designed to eliminate some or all of these six degrees of freedom of one member being coupled to another member.

Some examples of kinematic couplings are designed to constrain a member in question, providing precision and certainty of location. One example of a kinematic coupling includes three radial v-grooves in a first member that mate with three hemispheres in a second member. Each hemisphere in the second member has two contact points in a groove in the first member, for a total of six contact points, arranged to constrain all six of the part's degrees of freedom. An alternative example design includes three hemispheres on the first member that fit respectively into a tetrahedral dent, a v-groove, and a flat depression in the second member.

### INTRODUCTION

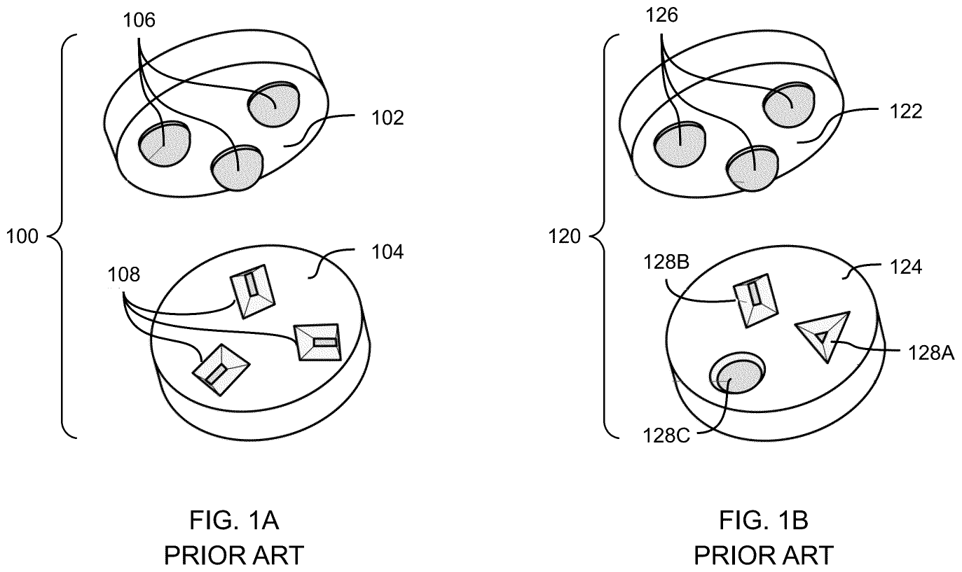

For purposes of better understanding some embodiments of the present disclosure, reference is first made to the construction and operation of a kinematic coupling as illustrated in FIGS. 1A-3B.

Reference is now made to FIG. 1A, which is a simplified line drawing of an isometric view of a kinematic coupling termed a Maxwell kinematic coupling according to prior art.

FIG. 1A shows a kinematic coupling 100 with a first member 102 which includes three hemispheres 106, and a second member 104, which includes three corresponding v-grooves 108.

It is noted that the first member 102 can thus be accurately positioned relative to the second member 104.

In some examples, and this is shown for example in FIG. 1A, the three v-grooves 108 are arranged so that the directions of the grooves are divided equally around a central point, that is, are arranged at an angle of 120 degrees relative to each other and intersecting at the central point.

Reference is now made to FIG. 1B, which is a simplified line drawing of an isometric view of a kinematic coupling termed a Kelvin kinematic coupling according to prior art.

FIG. 1B shows a kinematic coupling 120 with a first member 122 which includes three hemispheres 126, and a second member 124, which includes three corresponding depressions 128A 128B 128C. The first depression 128A is a tetrahedral dent 128A, which provides three contact points for a first hemisphere 126; the second depression 128B is a v-groove 128B which provides two contact points for a second hemisphere 126; and the third depression is a depression with a flat bottom, which provides one contact point for a third hemisphere 126.

It is noted that the first member 122 can thus be accurately positioned relative to the second member 124.

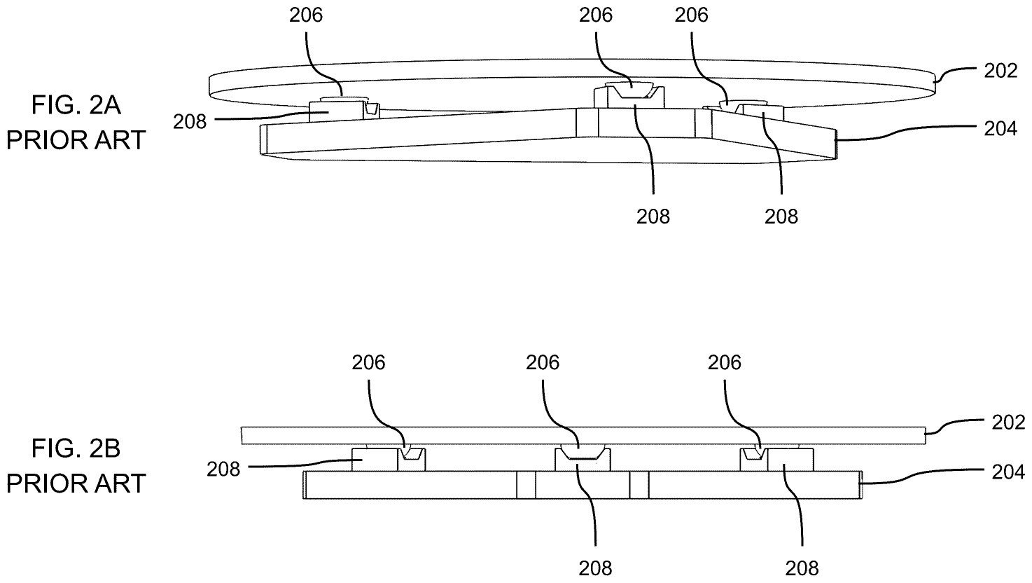

Reference is now made to FIGS. 2A and 2B, which are simplified line drawings of views of a Maxwell kinematic coupling when its members are coupled, according to prior art.

FIG. 2A is a tilted side view, and FIG. 2B is a side view.

FIGS. 2A and 2B show a first member 202 which includes three hemispheres 206, and a second member 204, which includes three corresponding v-grooves 208.

Referring now to a problem which may arise, and which examples of the present invention potentially solve, we describe non-limiting examples of members of kinematic couplings which should, in addition to repeatable location, maintain their shape and not deform.

In some examples, the first member 202 described in FIGS. 2A and 2B may be a chuck for holding a wafer, in the semiconductor manufacturing industry.

In some examples, the second member 204 described in FIGS. 2A and 2B may be a chuck holder as used in the semiconductor manufacturing industry.

It is noted that a chuck for holding a wafer is often thin, light, and hollow, with many holes on one surface, which is intended to attach a semiconductor wafer to the chuck by suction. The semiconductor wafer is ground flat, and it is important that neither the chuck nor the semiconductor wafer deform under conditions when the chuck is coupled to the chuck holder with a coupling force larger than just gravity.

Further details and examples may be described below in terms of the semiconductor manufacturing industry; however, they are intended to apply generally to kinematic couplings of one member to another member.

### Forces in Kinematic Coupling

Occasionally there may be a need to kinematically connect members using force.

One non-limiting example includes connecting a top chuck to a bottom chuck holder, when accelerations of the chuck holder may act upon the chuck to displace the chuck relative to the chuck holder.

Another non-limiting example includes connecting a first member to a second member, when the second member is inclined, and the hemispheres of the first member are not pressed strongly enough by gravity into their corresponding depressions in the second member.

Applying a force other than gravity between members of a kinematic coupling is termed herein, and in the claims, preloading the kinematic coupling, or applying a preloading force to the kinematic coupling.

Adding a preloading force to a kinematic coupling may require the members of the kinematic coupling to be designed stiffer, so as not to deform, or to deform less than some acceptable threshold.

By way of a non-limiting example, when one member of the kinematic coupling is a chuck intended to carry a semiconductor wafer, as is used in the semiconductor industry, if the chuck is deformed and not flat, it will not hold the wafer as intended. In many cases the chuck is hollow, to enable suction through the chuck to hold the wafer. A hollow chuck can be less stiff than a solid chuck.

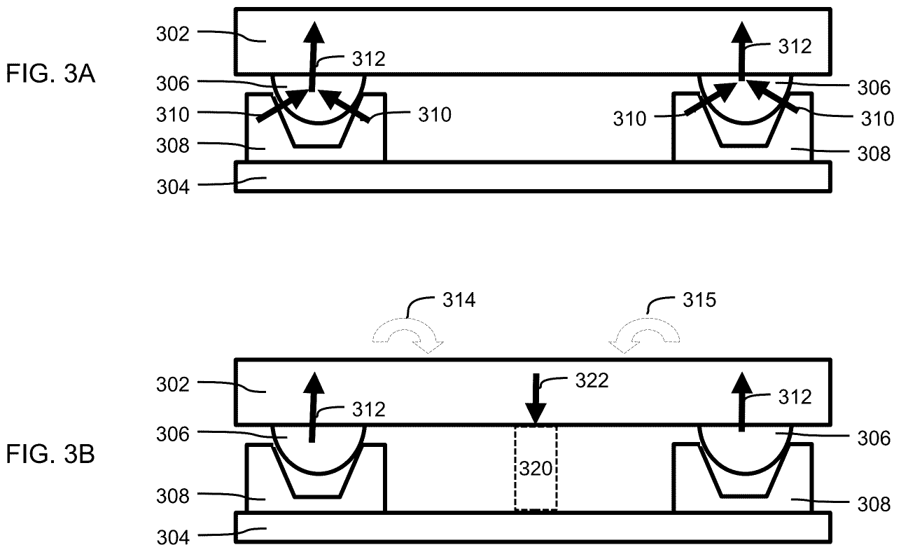

Reference is now made to FIG. 3A, which is a simplified line drawing of a cross section of a Maxwell kinematic coupling showing forces acting upon a chuck.

FIG. 3A shows forces acting upon a kinematic coupling which is not preloaded.

FIG. 3A shows a chuck 302 which includes hemispheres 306, and a chuck holder 304, which includes corresponding v-grooves 308. It is noted that the v-grooves 308 are not drawn to appear as being at an angle to each other but appear to be parallel. A person of skill in the art will appreciate that the following discussion of forces also holds true when the v-grooves 308 are at an angle to each other.

FIG. 3A shows that each one of the hemispheres 306 has two points of contact with an associated v-groove 308. At the points of contact a force 310 perpendicular to the contact surface acts upon the hemispheres 306. Each hemisphere 306 has two forces 310 acting upon it, producing a resultant force 312 perpendicular to the surface of the chuck 302.

Reference is now made to FIG. 3B, which is a simplified line drawing of a cross section of a Maxwell kinematic coupling showing added force acting upon a chuck.

FIG. 3B shows forces acting upon a kinematic coupling which is preloaded.

FIG. 3B shows a chuck 302 which includes hemispheres 306, and a chuck holder 304, which includes corresponding v-grooves 308. It is noted that the v-grooves 308 are not drawn to appear as being at an angle to each other but appear to be parallel. A person of skill in the art will appreciate that the following discussion of forces also holds true when the v-grooves 308 are at an angle to each other.

FIG. 3B also shows the resultant forces 312 described above with reference to FIG. 3A.

In case there is a need to draw the chuck 302 even more forcefully toward the chuck holder 304, an additional force 322 is applied, by some type of force-exerting component 320. The force-exerting component 320 applies a preloading force on the kinematic coupling shown in FIG. 3B.

However, applying the additional force 322 produces torque 314 315 to act upon the chuck 302. The additional force 322 does not act upon locations of support for the chuck 302, which are the kinematic couplings, but rather acts somewhere aside from the support, thus producing torque 314 315 upon the chuck 302. Such torque potentially bends or deforms the chuck 302.

It is noted that deforming the chuck may be deleterious to the purpose of the chuck.

By way of a non-limiting example, in the semiconductor industry the chuck 302 may serve as a holder for a semiconductor wafer (not shown in FIG. 3B), which is ground flat. If the chuck 302 is deformed to be not flat, it might not hold the wafer as intended.

Adding a Force to Kinematic Coupling without Deforming

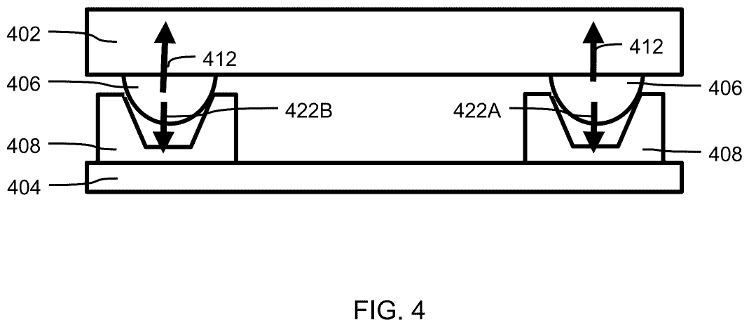

Reference is now made to FIG. 4, which is a simplified line drawing of a cross section of a Maxwell kinematic coupling showing added force acting upon a chuck, according to an example.

FIG. 4 shows a chuck 402 which includes hemispheres 406, and a chuck holder 404, which includes corresponding v-grooves 408. It is noted that the v-grooves 408 are not drawn to appear as being at an angle to each other but appear to be parallel. A person of skill in the art will appreciate that the following discussion of forces also holds true when the v-grooves 408 are at an angle to each other.

FIG. 4 also shows the resultant forces 412 effected by the v-grooves 408 on the hemispheres 406, described above with reference to FIG. 3A.

In case there is a need to draw the chuck 402 even more forcefully toward the chuck holder 404, one or more additional preloading forces 422A 422B are applied.

Applying the preloading force(s) 422A 422B does not produce torque as described with reference to FIG. 3B, since the force(s) 422A 422B are produced parallel to the direction of the supporting force 412 and are not displaced sideways of the supporting force 412. The preloading forces are produced coaxial to the resultant force 412 effected by the v-grooves 408 on the hemispheres 406.

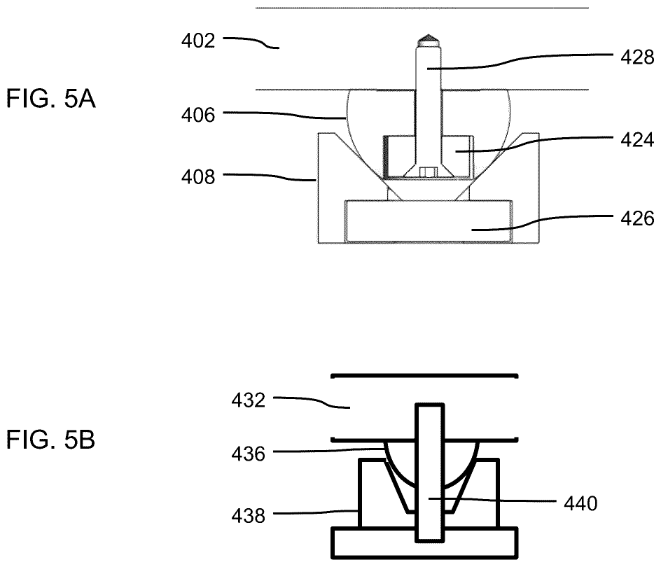

Reference is now made to FIG. 5A, which is a simplified line drawing of a cross section of a Maxwell kinematic coupling showing an arrangement for adding preloading force for coupling the kinematic coupling according to an example.

FIG. 5A shows a chuck 402 which includes a hemisphere 406 attached to the chuck by a connector 428, and a corresponding v-groove 408.

FIG. 5A also shows an optional first magnet 424 located coaxially with a central axis of the hemisphere 406, and an optional second magnet 426 located within the v-groove 408, also coaxial with the central axis of the hemisphere 406.

When the first magnet 424 acts to pull the second magnet 426, and vice versa, the pulling force is in line with the axis of the hemisphere 406 and does not apply a bending torque on the chuck 402.

In some cases, just one magnet may be used, by way of a non-limiting example only the first magnet 424. When the first magnet 424 acts to pull the v-groove 408, the pulling force is in line with the axis of the hemisphere 406 and does not apply a bending torque on the chuck 402.

By way of another non-limiting example only the second magnet 426 is used. When the second magnet 426 acts to pull the hemisphere 406, the pulling force is in line with the axis of the hemisphere 406 and does not apply a bending torque on the chuck 402.

It is noted that wherever the term magnet is used herein and in the claims the term should be taken to mean both a permanent magnet and an electromagnet.

Reference is now made to FIG. 5B, which is a simplified line drawing of a cross section of a Maxwell kinematic coupling showing an arrangement for adding force for coupling the kinematic coupling according to an example.

FIG. 5B shows a chuck 432 which includes a hemisphere 406 attached to the chuck 432, and a corresponding v-groove 438.

FIG. 5B also shows an optional coupling component 440 located coaxially with a central axis of the hemisphere 436, for pulling the chuck 432 toward the v-groove 438 and vice versa.

When the optional coupling component 440 pulls the chuck 432 toward the v-groove 438 the pulling force is in line with the axis of the hemisphere 436 and does not apply a bending torque on the chuck 432.

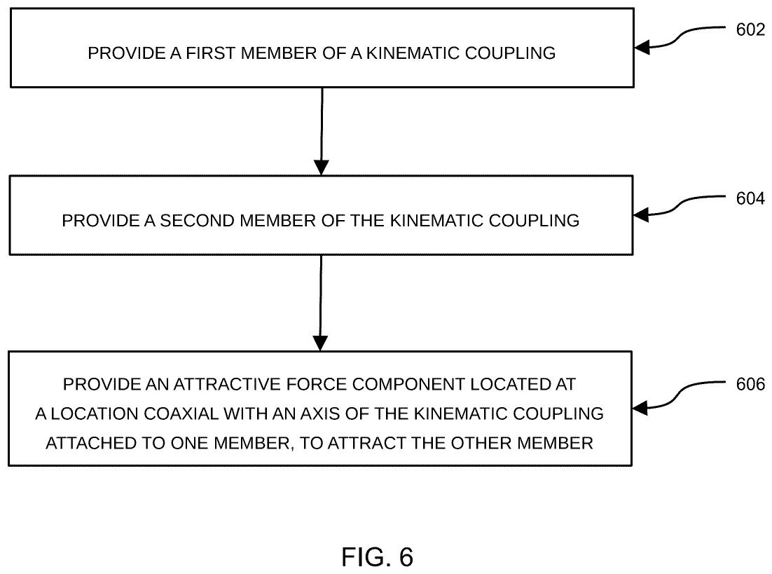

Reference is now made to FIG. 6, which is a simplified flow chart illustration of a method for increasing a coupling force between members of a kinematic coupling without inducing deformation of the members being coupled, according to an example.

The method of FIG. 6 includes:
providing a first member of a kinematic coupling (602);
providing a second member of the kinematic coupling (604); and
providing an attractive force component located at a location coaxial with an axis of the kinematic coupling attached to one member, to attract the other member (606),
thereby providing an attraction force between the first member and the second member directed along the axis of the kinematic coupling.

### SUMMARY OF THE PRESENT DISCLOSURE

### Example 1

A kinematic coupling for providing a preloading force without inducing deformation of the members being coupled, including a first member of a kinematic coupling, a second member of the kinematic coupling, and an attractive force component attached to at least one of the members of the kinematic coupling to attract the other member, wherein the attractive force component is located at a location coaxial with an axis of the kinematic coupling, thereby providing an attraction force between the first member and the second member directed along the axis of the kinematic coupling.

### Example 2

The kinematic coupling according to example 1, wherein the attractive force component includes a first magnet to magnetically attract the other member.

### Example 3

The kinematic coupling according to example 2, and further including a second magnet, wherein the second magnet is located at a location coaxial with an axis of the kinematic coupling attached to another member, to magnetically attract the first magnet.

### Example 4

The kinematic coupling according to any one of examples 2-3 wherein at least one of the magnets is an electromagnet.

### Example 5

The kinematic coupling according to any one of examples 1-4, wherein the kinematic coupling includes a Maxwell kinematic coupling.

### Example 6

The kinematic coupling according to any one of examples 1-4, wherein the kinematic coupling includes a Kelvin kinematic coupling.

### Example 7

The kinematic coupling according to any one of examples 1-6, wherein one of the members of the kinematic coupling includes a chuck for holding a semiconductor wafer.

### Example 8

A method for increasing a coupling force between members of a kinematic coupling without inducing deformation of the members being coupled, the method including providing a first member of a kinematic coupling, providing a second member of the kinematic coupling, and providing an attractive force component located at a location coaxial with an axis of the kinematic coupling attached to one member, to attract the other member, thereby providing an attraction force between the first member and the second member directed along the axis of the kinematic coupling.

### Example 9

The method according to example 8, wherein the attractive force component includes a first magnet to magnetically attract the other member.

### Example 10

The method according to example 9, and further including providing a second magnet wherein the second magnet is located at a location coaxial with an axis of the kinematic coupling attached to another member, to magnetically attract the first magnet.

### Example 11

The method according to any one of examples 9-10 wherein at least one of the magnets is an electromagnet.

### Example 12

The method according to any one of examples 8-11, wherein the kinematic coupling includes a Maxwell kinematic coupling.

### Example 13

The method according to any one of examples 8-11, wherein the kinematic coupling includes a Kelvin kinematic coupling.

### Example 14

The method according to any one of examples 8-13, wherein one of the members of the kinematic coupling includes a chuck for holding a semiconductor wafer.

As such, those skilled in the art to which the present invention pertains, can appreciate that while the present invention has been described in terms of preferred examples, the concept upon which this disclosure is based may readily be utilized as a basis for the designing of other structures, systems and processes for carrying out the several purposes of the present invention.

The various illustrative logical blocks, modules, and algorithm steps described in connection with the examples disclosed herein can be implemented as electronic hardware, computer software, or combinations of both. To clearly illustrate this interchangeability of hardware and software, various illustrative components, blocks, modules, and steps have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing any departure from the scope of the disclosure.

It will also be understood that the system according to the present disclosure may be, at least partly, implemented on a suitably programmed computer. Likewise, the present disclosure contemplates a computer program being readable by a computer for executing the method of the invention. The present disclosure further contemplates a non-transitory computer-readable memory tangibly embodying a program of instructions executable by the computer for executing the method of the present disclosure.

Also, it is to be understood that the phraseology and terminology employed herein are for the purpose of description and should not be regarded as limiting.

It should be noted that the words “comprising”, “including” and “having” as used throughout the appended claims are to be interpreted to mean “including but not limited to”. The indefinite articles “a” and “an,” as used herein in the specification and in the claims, unless clearly indicated to the contrary, should be understood to mean “at least one.”

It is important, therefore, that the scope of the invention is not construed as being limited by the illustrative examples set forth herein. Other variations are possible within the scope of the present invention as defined in the appended claims. Other combinations and sub-combinations of features, functions, elements and/or properties may be claimed through amendment of the present claims or presentation of new claims in this or a related application. Such amended or new claims, whether they are directed to different combinations or directed to the same combinations, whether different, broader, narrower or equal in scope to the original claims, are also regarded as included within the subject matter of the present description.

It is expected that during the life of a patent maturing from this application many relevant kinematic couplings may will be developed and the scope of the term kinematic coupling is intended to include all such new technologies a priori.

The terms “comprising”, “including”, “having” and their conjugates mean “including but not limited to”.

The term “consisting of” is intended to mean “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a unit” or “at least one unit” may include a plurality of units, including combinations thereof.

The words “example” and “exemplary” are used herein to mean “serving as an example, instance or illustration”. Any embodiment described as an “example or “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the disclosure may include a plurality of “optional” features unless such features conflict.

Unless otherwise indicated, numbers used herein and any number ranges based thereon are approximations within the accuracy of reasonable measurement and rounding errors as understood by persons skilled in the art

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. Certain features described in the context of various embodiments are not to be considered essential features of those embodiments, unless the embodiment is inoperative without those elements.

Although the disclosure has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A kinematic coupling for providing a preloading force without inducing deformation of the members being coupled, comprising:
a first member of a kinematic coupling;
a second member of the kinematic coupling; and
an attractive force component attached to at least one of the members of the kinematic coupling to attract the other member,
wherein the attractive force component is located at a location coaxial with an axis of the kinematic coupling,
thereby providing an attraction force between the first member and the second member directed along the axis of the kinematic coupling.

2. The kinematic coupling according to claim 1, wherein the attractive force component comprises a first magnet to magnetically attract the other member.

3. The kinematic coupling according to claim 2, and further comprising a second magnet,
wherein the second magnet is located at a location coaxial with an axis of the kinematic coupling attached to another member, to magnetically attract the first magnet.

4. The kinematic coupling according to claim 2 wherein at least one of the magnets is an electromagnet.

5. The kinematic coupling according claim 1, wherein the kinematic coupling comprises a Maxwell kinematic coupling.

6. The kinematic coupling according to claim 1, wherein the kinematic coupling comprises a Kelvin kinematic coupling.

7. The kinematic coupling according claim 1, wherein one of the members of the kinematic coupling comprises a chuck for holding a semiconductor wafer.

8. A method for increasing a coupling force between members of a kinematic coupling without inducing deformation of the members being coupled, the method comprising:
providing a first member of a kinematic coupling;
providing a second member of the kinematic coupling; and
providing an attractive force component located at a location coaxial with an axis of the kinematic coupling attached to one member, to attract the other member,
thereby providing an attraction force between the first member and the second member directed along the axis of the kinematic coupling.

9. The method according to claim 8, wherein the attractive force component comprises a first magnet to magnetically attract the other member.

10. The method according to claim 9, and further comprising providing a second magnet wherein the second magnet is located at a location coaxial with an axis of the kinematic coupling attached to another member, to magnetically attract the first magnet.

11. The method according to claim 9 wherein at least one of the magnets is an electromagnet.

12. The method according to claim 8, wherein the kinematic coupling comprises a Maxwell kinematic coupling.

13. The method according to claim 8, wherein the kinematic coupling comprises a Kelvin kinematic coupling.

14. The method according to claim 8, wherein one of the members of the kinematic coupling comprises a chuck for holding a semiconductor wafer.
